(19) United States
(12) Patent Application Publication
(10) Pub. No.: US 2014/0068390 A1
(43) Pub. Date: Mar. 6, 2014

(54) HYBRID DECODING OF BCH CODES FOR NONVOLATILE MEMORIES

(71) Applicants: Franz Schmidberger, Konstanz (DE); Christoph Baumhof, Radolfzell (DE); Axel Mehnert, Reichenau (DE); Steffen Allert, Konstanz (DE)

(72) Inventors: Franz Schmidberger, Konstanz (DE); Christoph Baumhof, Radolfzell (DE); Axel Mehnert, Reichenau (DE); Steffen Allert, Konstanz (DE)

(73) Assignee: HYPERSTONE GMBH, KONSTANZ (DE)

(21) Appl. No.: 14/115,022

(22) PCT Filed: Oct. 13, 2011
(86) PCT No.: PCT/DE2011/075251

§ 371 Date: Oct. 31, 2013

(51) Int. Cl. H03M 13/15

(52) U.S. Cl. CPC H03M 13/152
USPC 714/782

(57) ABSTRACT

An apparatus and a method for correcting data errors in a data block. The data block contains original data which are supplemented by such a security syndrome that the data block effects a correction of at most t data errors, wherein a parallel-operating quick corrector is used. The quick corrector is only designed for a correction of a subset t₁ of the set of the at most t data errors, and the quick corrector includes a test encoder, which sets a first test state flag P1 which, in the event of a complete correction of a processed data block, outputs this data block and secondly activates a series-operating post-corrector for at most t data errors. The output signal of the post-corrector is output as an alternative.

The invention relates to a method and an apparatus for correcting data errors using a Berlekamp-Massey algorithm, BMA, for Bose-Chandhuri Hacquenghem, BCH, decoding. Modern large memory systems composed of multi-level memory cells, MLC, in particular, have a relatively high error frequency compared to known single level memory cells, SLC, and thus require corrective devices for a significantly higher number of errors in a data block. This results in considerable time and/or space requirements.

The article by Wei Liu; Junrye Rho; Wonyong Sung, “Low-Power High-Throughput BCH Error Correction VLSI Design for Multi-Level Cell NAND Flash Memories” in the publication “Signal Processing Systems Design and Implementation, 2006. SIPS '06, pp. 303-308, October 2006” shows the relation between achievable correction time and hardware complexity in various circuit designs with different degrees of parallelization in algorithm representation, exemplarily using CMOS technology. For a fully parallel correction circuit, SiBM, a correction of up to t errors requires 2t field adders, 4t field multipliers, 2t+1 registers and 2t multiplexers, whereas an extremely folded version, SiBM-2t, only requires 1 field adder, 2 field multipliers and 2t+1 registers and 1 multiplexer. But instead of t clock cycles, the reduced version requires 2t² cycles. A simplified version, SiBM-2, reduces the circuit requirement by a half and doubles correction time to 2t clock cycles compared to the fully parallel version, SiBM, wherein in each case a simplified inversion-free Berlekamp-Massey method—SiBM—is implemented.

To save a considerable amount of time and energy, before each execution of an error correction, it is determined whether a data block is error-free, and if so, it is immediately released and no correction procedure is executed.

The article uses block diagrams, timing diagrams of subcircuits and an architecture overview to support the representation of the different configurations of a parallel or a serial operation. It does not, however, disclose a combination of different correction circuits with a complete circuit.

A detailed example of a fast parallel circuit is shown in U.S. Pat. No. 5,446,743.

Another example of a suitable serial circuit arrangement is presented in Hsie Chang-Chia; Shung, CB: “New serial architecture for the Berlekamp-Massey algorithm”, Communications, IEEE Transactions on, vol 47, no. 4, pp. 481-483, 4 Apr. 1999; it comprises 2 field adders, 3 field multipliers 2 multiplexers and 2t+1 registers.

It is the object of the invention to achieve, at a relatively low effort, a higher number of correctable errors, and averagely optimal time saving for correction of errors, and to further provide a dimensioning rule for the correction circuits.

The solution is a fully or partially parallel-operating error correction circuit, at the input side, for a subset of errors t1 of the set of at most t errors to be corrected, which is combined with a series-operating correction circuit that is used on demand.

Advantageous embodiments are specified in the dependent claims.

An optimization of the average required time is achieved by a suitable choice of the number of correctable errors t and the number of errors of the subset t1, taking into account the total length n of the data block to be processed, and the probability of the occurrence of t₂ errors (t t₂>t₁), for which a correction of the number of errors of the subset t1 would be insufficient.

The complete circuit comprises two correction devices which are on one side are connected to the SLC/MLC data memory via a first interface circuit, and on the other side are connected to a consumer, also called host, via another interface circuit. The data blocks passing through for storing are supplemented by the security data and stored in the memory in a known manner, e.g. by means of the BCH algorithm, and, in each case, after being read out by the testers and correctors, are delivered to the consumer without errors.

Error keys, which are also called syndromes, are commonly calculated for testing and correcting. They serve to determine the position of erroneous bits in the data block, and to correct these bits.

The invention is based on the finding that only a relatively small number of errors occurs in a majority of the read data blocks, so that for the correction of these errors, a relatively small parallel-operating, and correspondingly fast, circuit is necessary. Only in the minor number of cases in which there are still additional errors, an extremely simple series-operating correction circuit for this larger number of errors is used, the required time of which, however, shows a quadratic increase in relation to the number of correctable errors.

Alternatively, both correction circuits can be started simultaneously and optionally the process can be stopped after a successful completion of the parallel correction circuit. It is also possible to activate the serial circuit only in the event of an inadequate result of the parallel correction circuit, with the result of a slight additional delay. On the other hand, this allows to execute the serial operation by a relatively simple partial shutdown of the operator modules of the originally parallel correction device, and an additional activation of registers that are longer according to the ratio t to t₁.

A preferred separate implementation of the parallel and series-operating correction circuits provides redundancy, which is particularly advantageous in the event of a failure of the much more sophisticated parallel circuit, because in this case the serial, simpler correction circuit continues to operate, albeit with a greater delay.

The Bose-Chaudhuri-Hocquenghem code, BCH, recommended here is usually represented by polynomials, such as v(x)=u(x)x^{n-k}+(u(x)x^{n-k} mod g(x)), wherein the n bits of v(x) are determined from k information bits u(x) by means of a generator polynomial g (x). This is a polynomial of the lowest degree across a Galois field, the t roots of which correspond to the number of correctable errors. The BCH code results in root syndromes equaling zero, if there are no errors; and otherwise error polynomials occur, which each denote an error location.

In order to implement the invention, that is to execute a separate preliminary correction of a possibly low number of errors t₁, only the first 2t₁ coefficients of the root syndromes are used. This makes the code, which may be subject to a correction restricted to t₁ errors, a superset of the code, which may be fully corrected for t errors.

In the preferred example of a BMA-implementation for t₁ corrections with a parallel correction circuit SiBM-2, 2t₁ clock cycles are required for a complete correction operation. In addition, only in the cases in which there are more than t₁ errors, 2t² clock cycles of a SiBM-2 corrector are required for further correction, if both correction processes are performed sequentially, which is assumed here for simplicity.

Including the probability p of the occurrence of more than t₁ errors, this results in an average turnaround time of Nquer=2t₁+2pt², or more generally Nquer=at₁+bpt². Here, at₁ is the number of iterations for the parallel BMA, and bt² is the number of iterations for the serial BMA.

The conditional probability of p depends on t₁ and a raw bit error rate ε. It can be approximated for a binary symmetrical channel as

$$p = \frac{{\sum }_{i = {t}_{1} + 1}^{n} ( \begin{matrix}n \\ i\end{matrix} ) {{ɛ}^{i} ( 1 - ɛ )}^{n - i}}{1 - {( 1 - ɛ )}^{n}} ,$$

wherein n is the total number of bits in a secured data block and the counter indicates the probability that a number of errors greater than t₁ occurs, and the denominator indicates the probability that at least one error occurs in the n bits of a data block.

Therefore, in order to optimize t₁ with respect to the shortest possible average correction time Nquer, the latter must be less than or equal to the time required for a fully parallel correction: Nquer≦2t.

The combination apparatus according to the invention brings about an average gain of time of 2t−(2 t₁+p2t²) compared to a fully parallel correction apparatus, under the above conditions.

If t₁ is varied at a specified maximum number of correctable errors t, a given block length n and a known maximum block error rate ε, a maximum time saving results in each case. This is shown in the following three examples, wherein the residual error rate is set as lower than 10⁻¹⁶.

| | | |
|---|---|---|
| t = 24 | t = 48 | t = 96 |
| n = 8624 | n = 8960 | n = 9632 |
| εₜ = 24 = 3 * 10⁻⁴ | εₜ = 48 = 1.26 * | εₜ = 96 = 3.8 * |
| | 10⁻³ | 10⁻³ |
| t₁ₒₚₜᵢₘᵤₘ = 8 | t₁ₒₚₜᵢₘᵤₘ = 23 | t₁ₒₚₜᵢₘᵤₘ = 59 |
| p ≈ 1.4 * 10⁻³ | p ≈ 6.5 * 10⁻⁴ | p ≈ 2.3 * 10⁻⁴ |

In case 1, with a correction of up to 24 errors in 8624 bits, t₁=8 results in saving 32 cycles compared to 48 cycles of a parallel correction.

In case 2, with the possibility of correcting 48 bit of 8960 bit, t₁=23 results in a maximum saving of 49 cycles compared to otherwise 96 cycles.

In case 3, the maximum reduction results for t₁=59, so that 72 cycles, compared to 192 cycles, are saved.

Thus, very significant time savings can be achieved, in addition to an enormous reduction in circuit complexity, which can be derived from the listing of circuit components given in the introduction of Wei Liu et al. In case 1, the reduction of circuit complexity is, for t=24, t₁=8, with 24−(8+1) adders, 48−(16+2), multipliers, and 24−(8+1) multiplexers. Overall, therefore, the circuit dimension is approximately ⅓ of the fully parallel circuit. Case 2 results in a reduction of 48−(23+1) adders, 96−(46+2) multipliers, and 48−(23+1) multiplexers.

In Example 3, the reduction is 96−(59+1) adders, 192−(118+2) multipliers, and 96−(59+1) multiplexers. Again, almost half of the material is still saved.

A further reduction results from the fact, that in the case of a first, still incomplete correction, 2 t₁ syndrome values are already calculated, so that in the post-correction in serial correction mode, only 2t−2t₁ syndromes need to be determined if the ones that already exist are also used.

The examples given here for time optimization can analogously also be performed for other parallel correction apparatuses and other series correction apparatuses, as well as for different error rates and block lengths.

In particular, a further optimization can be brought about by determining the error probability distribution and taking it into consideration, also for mixed memory modules. Such memory combinations are often used, they contain in which a highly used portion of memory blocks consists of simple elements, and the rest consists of multiply used memory elements with a higher error rate.

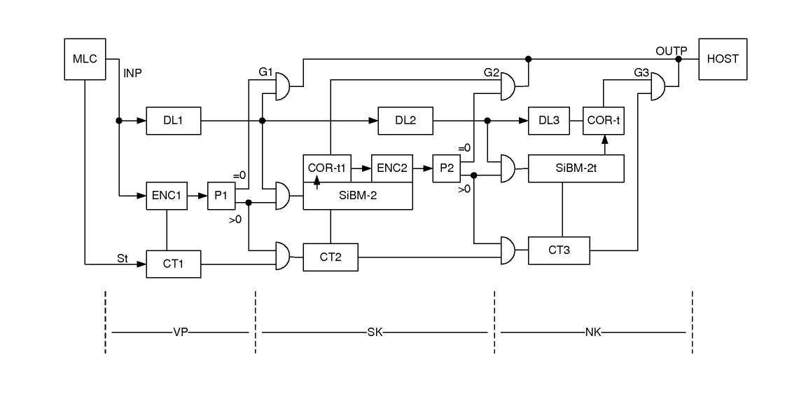

The block diagram, FIG. 1, shows the operation of the novel apparatus.

The circuit diagram is based on the diagram in Wei Liu et al. a.a.O., FIG. 12. It illustrates the division of the complete apparatus into three portions: the preliminary tester VP, the quick corrector SK and the post-corrector NK.

The input data from a memory MLC, coming from the input INP, pass the first test encoder ENC1 and a parallel first delay register DL1 to bridge the testing period. If the test result is 0, that is, correct, the test state flag P1 feeds the output of the first delay element DL1, through a first AND gate G1 in a wired OR-circuit, to the output OUTP.

If the preliminary test shows that the data block is erroneous, i.e. P1>0, the output of the first delay element DL1 is fed to the quick corrector SK, which consists of the parallel corrector SiBM-2, designed for t₁ error corrections. It operates on a simplified inversion-free Berlekamp-Massey method as it is described, for example, in FIG. 8 of the document Wei Liu et al a.a.O., and operates the error corrector COR-t₁, the corrected output signal of which is checked by a second test encoder ENC2 that triggers the test state flag P2.

In case of correctness, said test state flag feeds the output of the first corrector

COR-t₁, via a second AND gate G2 to the output OUTP, in the other case, the uncorrected data block, through the first and the second delay register DL1, DL2, is supplied to the post-corrector NK. Said post-corrector consists of a series-operating corrector SiBM-2t as it is described, for example in FIG. 10 of the document Wei Liu et al a.a.O. Via the corrector SiBM-2t, a second error corrector COR-t is connected for t correction locations. The output signal from the third delay register DL3, downstream of the second delay register DL2, is supplied to said error corrector COR-t, the corrected output signal of which is directed, via the AND gate D3, to the output OUTP, to which an operating device HOST is connected.

All three circuit portions are controlled by a respective associated controller CT1, CT2, CT3. The first controller CT1 is triggered by a suitable start signal St, which is derived from the memory MLC. The further controllers CT2, CT3 are started depending on the respectively associated test state flag P1, P2 in the event of an error.

Instead of the serial connection of the three circuit [symbol] portions VP, SK, NK, which is shown here for clarity, it is also possible, as previously described, to implement a parallel circuit of two or all three portions. The circuit portions that are still operating can then be switched off by releasing one of the output gates G1, G2, G3.

This does not change the basic principle of the invention. Similarly, variants with even faster parallel or serial controllers can be implemented. Also, the security encryption can be performed by one of the other methods, and used for correction.

### REFERENCES

at1 number of iterations for the parallel BMA
bt² number of iterations for the serial BMA
c, d, e, f, g numbers of components of the post-corrector
T-COR, COR-t₁ error correction of t and t1 errors
CT1-CT3 controllers
DL1-DL3 delay registers
ENC1, ENC2 test encoders
G1-G3 AND gate
h, i, j, k number of components of the quick corrector
HOST operating device
INP input
l cycles saved
MLC multi-level memory
m exponent of acceptable residual error probability
NK post-corrector
n total number of bits in a saved data block
OUTP output
P1, P2 test state flags
p probability of occurrence of more than t₁ errors
r residual error probability
SiBM-2 correction calculator, parallel
SiBM-2t correction calculator, serial
SK quick corrector
St start signal
t maximum number of correctable data errors
t1 number of quickly correctable data errors
VP preliminary test
ε raw bit error rate

1-17. (canceled)

18. A method of correcting data errors in a data block having a length of n bits, containing original data which are supplemented by security information that at most a maximum number t of data errors are correctable, the method comprising:
providing an apparatus having a quick corrector operating with a parallel SiBM correction calculator, wherein the quick corrector is configured for a correction of only a subset of errors t₁ of the maximum number t of data errors and includes a syndrome calculation circuit;
setting a test state flag P2 with the syndrome calculation circuit, the test flag P2 indicating whether the quick corrector was able to correct all existing errors, and, in the event of a failed correction attempt of a data block, activating a post-corrector operating with a serial SiBM correction calculator for a maximum number t of data errors;
in order to optimize a dimension of the quick corrector, determining the subset of errors t₁ for a probability p of an occurrence of more than t₁ errors in a data block, by calculating an average turnaround time Nquer through the apparatus, which is determined by a sum of a number of operating cycles 2t₁ of the quick corrector and a probable number of operating cycles 2pt² of the post-corrector, and then maximizing a reduction in the number of cycles by calculating 2t−(2t₁+2pt²) while varying t₁.

19. The method according to claim 18, which comprises approximating the probability p with respect to a raw error rate c of a binary symmetrical channel according to the formula
$$p = \frac{{\sum }_{i = {t}_{1} + 1}^{n} ( \begin{matrix}n \\ i\end{matrix} ) {{ɛ}^{i} ( 1 - ɛ )}^{n - i}}{1 - {( 1 - ɛ )}^{n}} .$$

20. The method according to claim 18, which comprises the only the first 2t₁ coefficients of the root syndromes of the maximum number of errors t are used for the error subset t₁ of the quick corrector.

21. The method according to claim 18, wherein the quick corrector and the post-corrector operate according to an inversion free Berlekamp-Massey method, BMA, and use Bose-Chaudhuri-Hocquenghem coding, BCH.

22. An apparatus for correcting data errors in a data block having a length of n bits, containing original data which are supplemented by such security information that at most t data errors are correctable, the apparatus comprising:
a quick corrector configured for a correction of a subset of errors t₁ of a maximum number of data errors t and a series-operating post-corrector for a maximum of t data errors;
said quick corrector being configured to output a processed data block in the event of a complete correction of the processed data block and said post-corrector being configured to correct and output the data block in the event of an incomplete correction by said quick corrector; and
wherein the apparatus is dimensioned in accordance with the method according to claim 18.

23. The apparatus according to claim 22, which further comprises a first input side syndrome calculation circuit, configured to generate a result suitable for detecting errors in the supplied data block and which, if no errors are detected, for directing the data block to an output.

24. The apparatus according to claim 22, wherein said quick corrector is based on a correction calculator having 2t₁ field adders, 4t₁ field multipliers, 2t₁+1 registers, and 2t₁ multiplexers.

25. The apparatus according to claim 23, which further comprises a second syndrome calculation circuit, wherein said quick corrector is configured to examine, by way of said second syndrome calculation circuit, the data for errors and, depending on a result, to either release these data for output or activate or release said post-corrector.

26. The apparatus according to claim 22, wherein said post-corrector is implemented by selectively switching components of said quick corrector.

27. The apparatus according to claim 22, configured for a block length of n=8960 bits and a number of errors to be corrected t=48, with the subset of errors being t₁=23.
